(19) United States
(12) Patent Application Publication
(10) Pub. No.: US 2026/0308800 A1
(43) Pub. Date: Oct. 8, 2026

(54) INGOT GROWTH DEVICE AND METHOD FOR CONTROLLING INGOT GROWTH

(71) Applicant: HANWHA SOLUTIONS CORPORATION, Seoul (KR)

(72) Inventors: Ji Wook SEO, Seoul (KR); Young Hwan LEE, Seoul (KR); Dong Ki PARK, Seoul (KR)

(73) Assignee: HANWHA SOLUTIONS CORPORATION, Seoul (KR)

(21) Appl. No.: 19/478,981

(22) PCT Filed: Mar. 14, 2024
(86) PCT No.: PCT/KR2024/095533

§ 371 Date: Oct. 27, 2025

(30) Foreign Application Priority Data
Apr. 26, 2023 (KR) 10-2023-0054997

(51) Int. Cl. C30B 15/02; C30B 15/10; C30B 15/14; C30B 15/22; C30B 15/30; C30B 29/06

(52) U.S. Cl. CPC C30B 15/02; C30B 15/10; C30B 15/14; C30B 15/22; C30B 15/30; C30B 29/06

(57) ABSTRACT

An ingot growth device may include an ingot growth furnace including a main crucible, an auxiliary melting furnace which supplies molten silicon to the ingot growth furnace, a silicon feeder including a solid silicon transfer path connected to the auxiliary melting furnace and a transfer member which is connected to the solid silicon transfer path and transfers solid silicon, the ingot growth furnace may further include a melt gap measuring device, and a controller may increase a supply amount of the solid silicon of the silicon feeder or increase an output of the auxiliary melting furnace when the melt gap is lower than a range of a normal melt gap, and decrease the supply amount of the solid silicon of the silicon feeder or decrease the output of the auxiliary melting furnace when the melt gap is higher than the range of the normal melt gap.

### TECHNICAL FIELD

The present disclosure relates to an ingot growth device and a method of controlling ingot growth.

### BACKGROUND ART

The Czochralski crystal growth method is one method of manufacturing single crystal silicon wafers which are raw materials of semiconductors, and in the Czochralski crystal growth method, silicon is input to a crucible, heated, and melted. In addition, a single crystal seed is brought into contact with the molten silicon and moved upward while being rotated in one direction to grow an ingot with a predetermined diameter. Within the Czochralski crystal growth method, a method of growing an ingot by continuously injecting a silicon material into a crucible is called a continuous growth type Czochralski method.

A method of melting a solid silicon in an auxiliary melting furnace and then supplying a molten silicon to an ingot growth furnace in order to continuously grow an ingot is being studied. However, when the molten silicon is supplied to the ingot growth furnace, since it is difficult to maintain a constant interface of the molten silicon, an ingot growth device using the method is not commercialized well.

In particular, in order to supply molten silicon to an ingot growth furnace after solid silicon is melted, a constant height of a melt gap which is a distance between the interface of the molten silicon accommodated in a main crucible and a reflector should be maintained. In this process, an amount of the solid silicon input to the auxiliary melting furnace, an amount of the molten silicon supplied to the ingot growth furnace from the auxiliary melting furnace, an amount of the molten silicon accommodated in the ingot growth furnace, and a growth rate of an ingot should be considered. In addition, in a process in which molten silicon is moved to an ingot growth furnace from an auxiliary melting furnace, the molten silicon is cooled down and is solidified again, or a temperature of the ingot growth furnace is decreased, and thus there is a problem that the quality and yield of the ingot is lowered.

The above-described background art is technical information that the inventor had when deriving the present invention or obtained while deriving the present invention, and is not necessarily known technology that was disclosed to the general public prior to the application of the present invention.

### DETAILED DESCRIPTION OF INVENTION

### Technical Problem

The present disclosure is directed to providing an ingot growth device and a method of controlling ingot growth, which improve the quality and yield of an ingot by maintaining a constant melt gap of molten silicon while supplying the molten silicon in a main crucible to an ingot growth furnace.

However, the objects are only exemplary, and objects to be solved by the present disclosure are not limited thereto.

### Technical Solution

One aspect of the present invention provides an ingot growth device including an ingot growth furnace including a main crucible, an auxiliary melting furnace which supplies molten silicon to the ingot growth furnace, a silicon feeder including a solid silicon transfer path connected to the auxiliary melting furnace and a transfer member which is connected to the solid silicon transfer path and transfers solid silicon, and a controller which controls at least one of the ingot growth furnace, the auxiliary melting furnace, and the silicon feeder, wherein the ingot growth furnace further includes a melt gap measuring device which measures a melt gap which is a height between an interface of the molten silicon accommodated in the main crucible and a reflector located above the main crucible, and the controller increases a supply amount of the solid silicon of the silicon feeder or increases an output of the auxiliary melting furnace, when the melt gap is lower than a predetermined range of a normal melt gap, and decreases the supply amount of the solid silicon of the silicon feeder or decreases the output of the auxiliary melting furnace when the melt gap is higher than the range of the normal melt gap.

The controller may adjust the supply amount of the solid silicon by controlling at least one of control factors including power, a vibration period, and a vibration magnitude of the transfer member which is a vibrator.

The ingot growth furnace may further include a pulling wire in which a seed is connected to an end portion of the pulling wire and a pulling device which pulls or rotates the pulling wire upward, wherein, when the melt gap is outside of the range of the normal melt gap, the controller may control one or more of a rotation speed and a pulling speed of the pulling wire using the pulling device.

The ingot growth furnace may include a transfer path which receives the molten silicon from the auxiliary melting furnace and transfers the molten silicon to the main crucible and includes a maintaining heater, and the controller may operate the transfer member and increase an output of the maintaining heater to a raised temperature output at the same time.

The controller may output an alarm signal when the raised temperature output of the maintaining heater is outside of a range of a normal raised temperature output, or the raised temperature output of the maintaining heater does not reach the range of the normal raised temperature output in a predetermined time from a time point at which the transfer member operates.

The controller may operate the maintaining heater while the transfer member does not operate and maintain the output of the maintaining heater as an idle output to be greater than zero and lower than the range of the normal raised temperature output.

Another aspect of the present invention provides a method of controlling ingot growth including supplying molten silicon to an ingot growth furnace and growing single crystal silicon while heating the molten silicon, wherein the supplying of the molten silicon to the ingot growth furnace includes supplying solid silicon from a silicon feeder to an auxiliary melting furnace, melting the solid silicon in the auxiliary melting furnace, and supplying the molten solid silicon to the ingot growth furnace, the growing of the single crystal silicon includes measuring a melt gap of the molten silicon accommodated in a main crucible of the ingot growth furnace, and, in the measuring of the melt gap, a supply amount of the solid silicon of the silicon feeder is increased, or an output of the auxiliary melting furnace is increased when the measured melt gap is lower than a range of a normal melt gap, and the supply amount of the solid silicon of the silicon feeder is decreased, or the output of the auxiliary melting furnace is decreased when the measured melt gap is higher than the range of the normal melt gap.

The ingot growth furnace may further include a pulling wire in which a seed is connected to an end portion of the pulling wire and a pulling device which pulls or rotates the pulling wire upward, wherein, in the measuring of the melt gap, when the melt gap is outside of the range of the normal melt gap, the pulling device may control one or more of a rotation speed and a pulling speed of the pulling wire.

The ingot growth furnace may include a transfer path which receives the molten silicon from the auxiliary melting furnace and transfers the molten silicon to the main crucible and includes a maintaining heater, the silicon feeder may include a transfer member which transfers the solid silicon, and in the supplying of the molten solid silicon to the ingot growth furnace, when a raised temperature output of the maintaining heater is outside of a range of a normal raised temperature output, or the raised temperature output of the maintaining heater does not reach the range of the normal raised temperature output in a predetermined time from a time point at which the transfer member operates, the controller may perform feedback control such that the raised temperature output of the maintaining heater is in the range of the normal raised temperature output.

The controller may operate a maintaining heater while the transfer member does not operate and maintain an output of the maintaining heater as an idle output to be greater than zero and lower than a range of a normal raised temperature output.

Other aspects, features, advantages in addition to the above-described contents will be clear from specific contents, claims, and drawings for implementing the invention below.

### Advantageous Effects

An ingot growth device and a method of controlling ingot growth according to embodiments of the present disclosure can produce an ingot with superior quality by measuring a melt gap in an ingot growth furnace and maintaining a proper range of the melt gap using a controller. In particular, according to the ingot growth device and the method of controlling ingot growth, feedback control can be performed on a melt gap by determining whether the melt gap is lower or higher than a range of a normal melt gap and controlling supply amounts of solid silicon and molten silicon based on the determination.

An ingot growth device and a method of controlling ingot growth according to embodiments of the present disclosure can improve the quality of an ingot by heating molten silicon supplied to an ingot growth furnace from an auxiliary melting furnace to prevent the molten silicon from being solidified or prevent a temperature of the molten silicon from being decreased. In particular, the ingot growth device and the method of controlling ingot growth can optimize an operation of increasing and decreasing a temperature of a heater and improve the reliability of the device by controlling the heater of a transfer path in conjunction with supply of solid silicon.

### DESCRIPTION OF DRAWINGS

FIG. 1 schematically shows an ingot growth device.

FIG. 2 shows a state in which an ingot growth furnace is connected to an auxiliary melting furnace.

FIG. 3 shows a state in which the auxiliary melting furnace is connected to a silicon feeder.

FIG. 4 shows a state in which the ingot growth furnace is connected to the silicon feeder.

FIG. 5 shows an inner portion of the ingot growth furnace.

FIG. 6 shows a first transfer path in detail.

FIG. 7 shows an inner portion of the auxiliary melting furnace.

FIG. 8 shows an inner portion of the silicon feeder.

FIG. 9 briefly shows a control block diagram of a controller.

FIG. 10 briefly shows a flowchart of controlling a melt gap.

FIG. 11 briefly shows a flowchart of controlling an output of a maintaining heater.

FIG. 12 shows a graph of an output of the maintaining heater over time.

FIG. 13 shows a graph of an output of a maintaining heater over time according to another embodiment of the present invention.

### BEST MODE OF THE INVENTION

An ingot growth device may include an ingot growth furnace including a main crucible, an auxiliary melting furnace which supplies molten silicon to the ingot growth furnace, a silicon feeder including a solid silicon transfer path connected to the auxiliary melting furnace and a transfer member which is disposed at one side of the solid silicon transfer path and transfers solid silicon, and a controller which controls at least one of the ingot growth furnace, the auxiliary melting furnace, and the silicon feeder, wherein the ingot growth furnace may further include a melt gap measuring device which measures a melt gap which is a height between an interface of the molten silicon accommodated in the main crucible and a reflector disposed above the main crucible, and the controller may increase a supply amount of the solid silicon of the silicon feeder or increase an output of the auxiliary melting furnace when the melt gap is lower than a predetermined range of a normal melt gap, and decrease the supply amount of the solid silicon of the silicon feeder or decrease the output of the auxiliary melting furnace when the melt gap is higher than the range of the normal melt gap.

### Modes of the Invention

Embodiments of the present disclosure may be understood with reference to the descriptions and accompanying drawings of the invention. The embodiments which will be described may have various modified embodiments and be implemented in various different forms and are not limited to the embodiments described in the present specification. In addition, features of the various embodiments of the present disclosure may be partially or entirely combined. The embodiments may be implemented independently of or in relation to each other. The described embodiments are provided as examples such that the present disclosure is complete and is to completely transfer the spirit of the present disclosure to those skilled in the art to which the present disclosure belongs. The present disclosure may be substituted by modifications and equivalents within the spirit and technical ranges of the present invention. Accordingly, processes, elements, and technologies that are not necessary for those skilled in the art for complete understanding of the embodiments of present disclosure may not be described.

Unless otherwise additionally illustrated in the accompanying drawings and described elsewhere in the specification, since the same reference symbols, letters, or combinations thereof indicate the same components, redundant descriptions thereof will be omitted. In addition, portions unrelated to descriptions will be omitted to clearly describe the present invention.

In the drawings, relative sizes of elements, layers, and regions may be exaggerated for clarity. In the accompanying drawings, hatching and/or shading is generally used to clarify a boundary between adjacent elements. Accordingly, the presence of the hatching or shading does not indicate a specific material, a material feature, a dimension, a ratio, a commonality between drawn elements and/or other features, properties, and exemplary forms or requirements for the properties of an element unless otherwise indicated.

Various embodiments will be described in the present specification with reference to examples and/or exemplary cross sections which are schematic examples of intermediate structures. Accordingly, for example, a shape in a drawing may be changed as a result of a manufacturing technology and/or a tolerance. In addition, a specific structural or functional description described in the present specification is merely exemplary for describing an embodiment according to a concept of the present invention. Accordingly, the embodiments disclosed in the present specification should not be interpreted as being limited to shapes of illustrated regions, and, for example, include deviations of forms according to manufacturing.

A region illustrated in a drawing is essentially a schematic region, and a shape of the region is not for illustrating an actual shape of the region of an apparatus and is not intended to limit the shape. In addition, as will be recognized by those skilled in the art, embodiments which will be described may be modified in various manners within a region not departing from the spirit and scope of the present disclosure.

In the specification, several specific details are suggested to provide complete understanding of various embodiments. However, the various embodiments may be made without the specific details or with one or more of the specific details. In another case, well-known structures and apparatuses will be illustrated in forms of block diagrams in order to avoid unnecessarily obscuring the various embodiments.

As illustrated in the drawings, spatially relative terms, such as “below,” “above,” “lower,” and “upper,” may be used here in order to easily describe relationships between features of one element and features of another element. The spatially relative terms are intended to include various directions of used or operated apparatuses in addition to directions illustrated in the drawings. For example, when an apparatus in a drawing is turned upside down, one element having a feature described as being “below” or “under” another element may then be located above the other element. Accordingly, the illustrative terms, such as “below” and “under,” may indicate both upward and downward directions. An apparatus may face in different directions (for example, turned 90° or facing in another direction), and a spatially relative description used in the present specification should be interpreted accordingly. Similarly, when a first portion is described as being disposed above a second portion, it means that the first portion is disposed above or below the second portion.

In addition, descriptions such as “viewed on a plane” means that an object is viewed from above, and descriptions such as “in a schematic cross-sectional view” mean that an object is vertically cut and a schematic cross section thereof is viewed. Descriptions such as “laterally viewed” mean that a first object may be disposed above, below, or beside a second object and the inverse case is also possible. In addition, terms such as “overlapping” or “superposition” may include layering, stacking, facing, extending, covering, partially covering, or any other suitable term understood by those skilled in the art. Terms such as “not overlapping” may include a meaning of “separated from” or “spaced apart from” and any other equivalent suitable term recognized and understood by those skilled in the art. Terms such as “side” and “surface” may mean that a first object may directly or indirectly face a second object. When a third object is located between a first object and a second object, it may be understood that the first object and the second object face each other or indirectly face each other.

When an element, layer, region, or component is described as being “formed on,” “connected to,” or “coupled to” another element, layer, region, or component, the element, layer, region, or component may be directly formed thereon, formed on another element, layer, region, or component, or indirectly formed on, connected to, or coupled to the other element, layer, region, or component. In addition, descriptions such as “formed on,” “connected to,” or “coupled to” may generally mean direct or indirect coupling or connection or integral or nonintegral coupling or connection between elements, layers, regions, or components with one or more other elements, layers, regions, or components present. For example, when an element, layer, region, or component is described as being “electrically connected” or “electrically coupled” to another element, layer, region, or component, the element, layer, region, or component may be directly electrically connected or coupled the other element, layer, region, or component, or still another element, layer, region, or component may be present therebetween. However, descriptions such as “direct connection” or “direction coupling” mean that one component is directly connected to, coupled to, or located on another component with no other component therebetween. In addition, in the present specification, in a case in which a portion of a layer, a film, a region, a guide plate, or the like is formed on another portion, a forming direction thereof is not limited to an upward direction and the portion may be formed on a side surface or a lower portion of the other portion. Conversely, cases in which a portion of a layer, film, region, guide plate, or the like is formed “under” another portion includes not only a case in which the portion is disposed directly under the other portion but also a case in which still another portion is located between the portion and the other portion. Meanwhile, other descriptions for describing relationships between components, such as “between,” “exactly between,” “adjacent to,” and “directly adjacent to” may be similarly interpreted. In addition, when an element or layer is described as being located “between” two elements or layers, the element may be only one element located between the two elements or layers, or there may be another element therebetween.

For an object of the present specification, descriptions such as “at least one or more” or “any one” do not limit an order of individual elements. For example, “at least one of X, Y, and Z,” “at least one of X, Y, or Z,” or “at least one selected from the group consisting of X, Y, and Z” may include a single X, a single Y, a single Z, or any combination of two or more of X, Y and Z. Similarly, descriptions such as “at least one of A and B” and “at least one of A or B,” may include A, B, or A and B. In the present specification, terms such as “and/or” includes any combination of one or more related items. For example, the description “A and/or B,” may include A, B, or A and B.

Terms such as “first,” “second,” and “third” may be used in the present specification to describe various elements, components, regions, layers, and/or cross sections, but the elements, components, regions, layers, and/or cross sections are not limited by such terms. Such terms are used to distinguish an element, component, region, layer, or cross section from another element, component, region, layer, or cross section. Accordingly, a first element, component, region, layer, or cross section which will be described below may be termed a second element, component, region, layer, or cross section without departing from the spirit and scope of the present invention. The description of an element as a “first element” may not require or imply a second element or another element. Terms such as “first” or “second” may also be used in the present specification to distinguish different categories or element sets. For clear description, terms such as “first” or “second” may indicate a “first category (or first set),” “second category (or second set),” or the like.

The terminology used herein is for the purpose of describing specific embodiments only and is not intended to limit the present invention. As described in the present specification, the singular forms are intended to include the plural forms, and unless the context clearly indicates otherwise, the plural forms are intended to include the singular forms. In the present specification, terms such as “comprise,” “include,” and “have” used in the present specification are meant to specify the presence of stated features, numbers, and steps thereof. The terms do not preclude the presence or addition of one or more other functions, steps, operations, components, and/or groups thereof.

When one or more embodiments may be implemented in different manners, a specific process may be performed according to an order different from a described order. For example, two processes that are sequentially described may be actually simultaneously performed or performed in an order opposite to a described order.

Terms such as “actually,” “about,” “substantially,” and similar terms are used as terms of approximation, and mean that a range of an intrinsic deviation (for example, a deviation range due to the limitation of a measurement system) of a measured or calculated value is satisfied. For example, terms such as “about” may mean within a standard deviation of one or more values or a range within ±30%, 20%, 10%, or 5% of a stated value.

Unless otherwise defined, all terms including technical and scientific terms used herein have meanings which are the same as meanings generally understood by those skilled in the art. Terms such as those defined in commonly used dictionaries should be interpreted as having meanings that are consistent with their meanings in the context of the relevant art and will not be interpreted in an idealized or overly formal sense unless explicitly defined here.

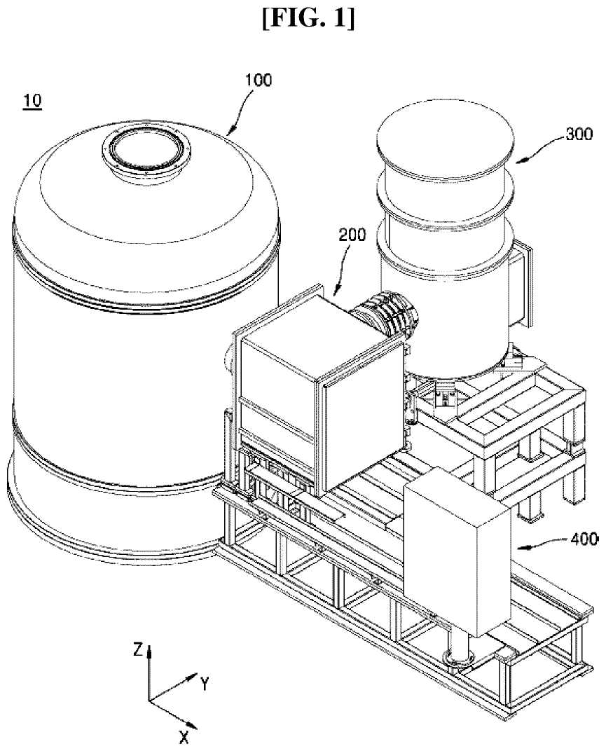

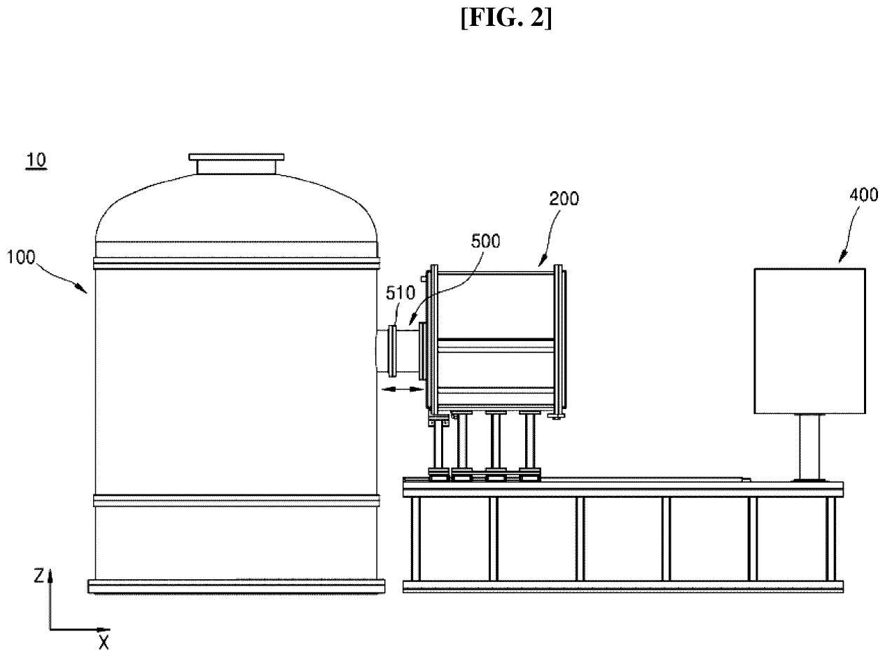

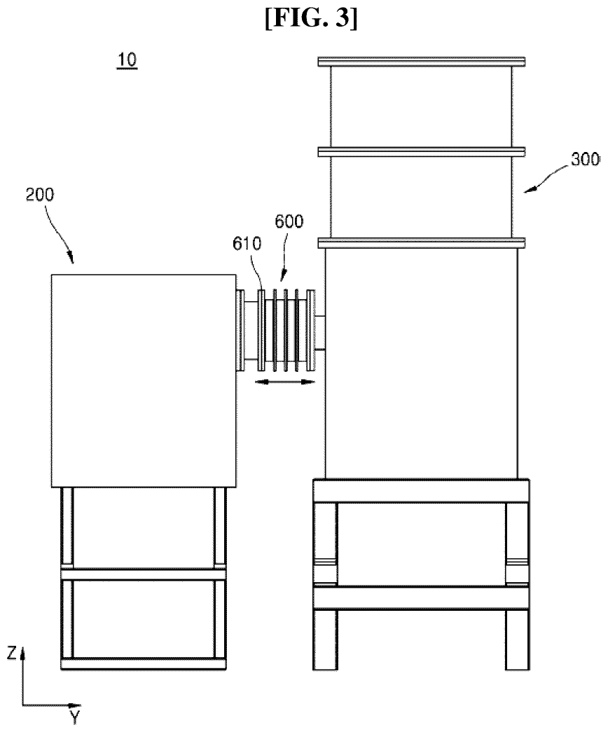

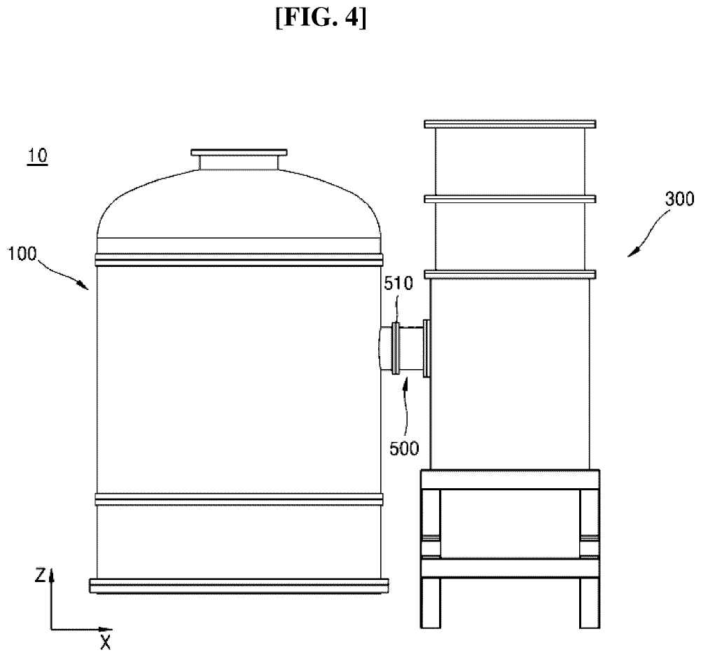

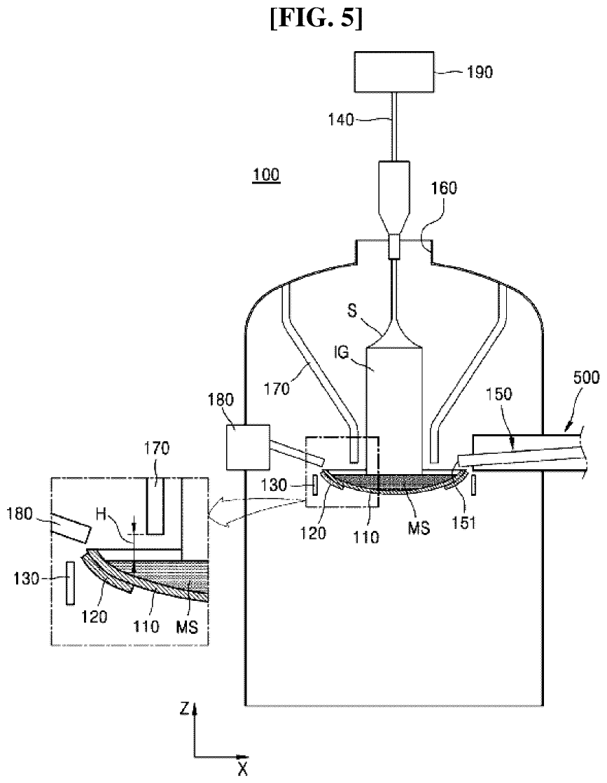

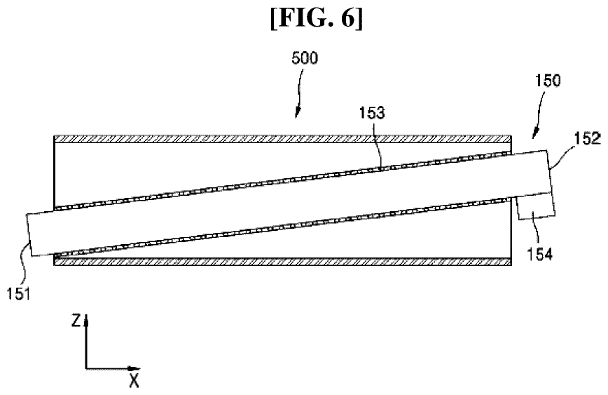

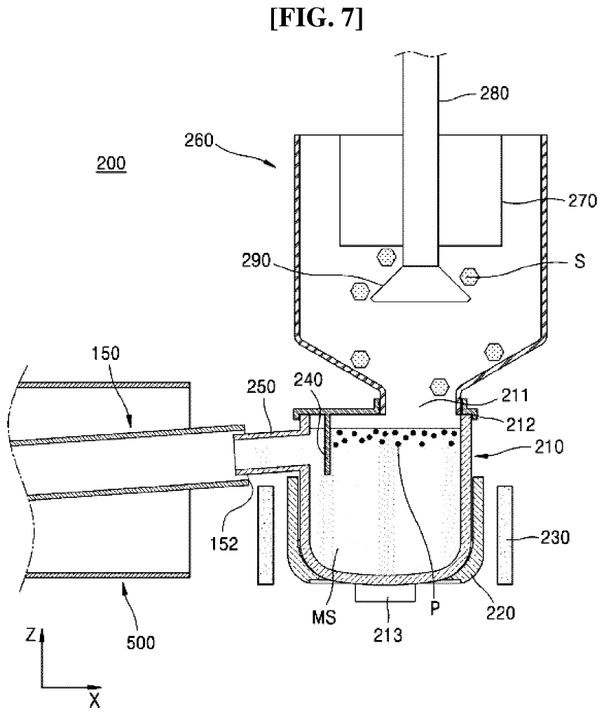

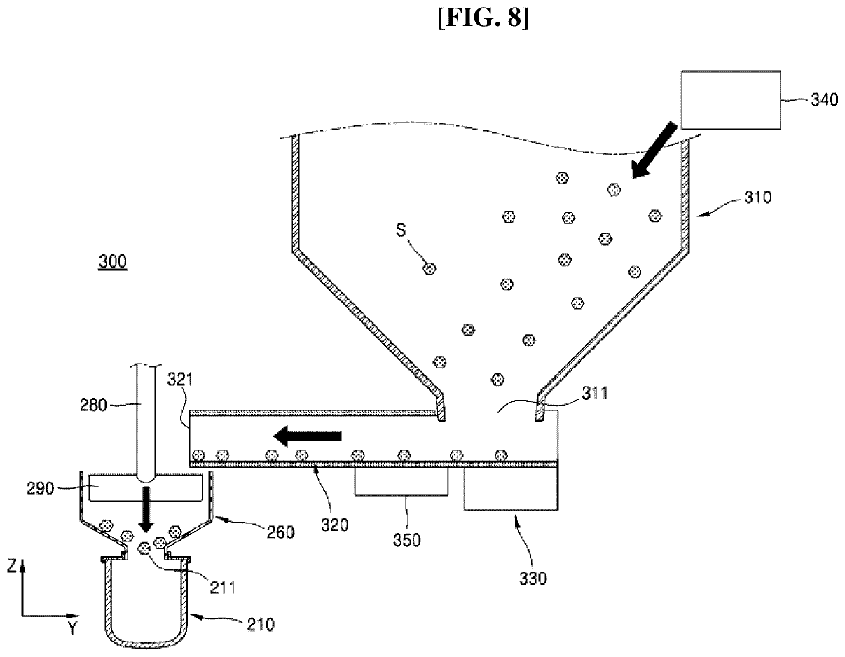

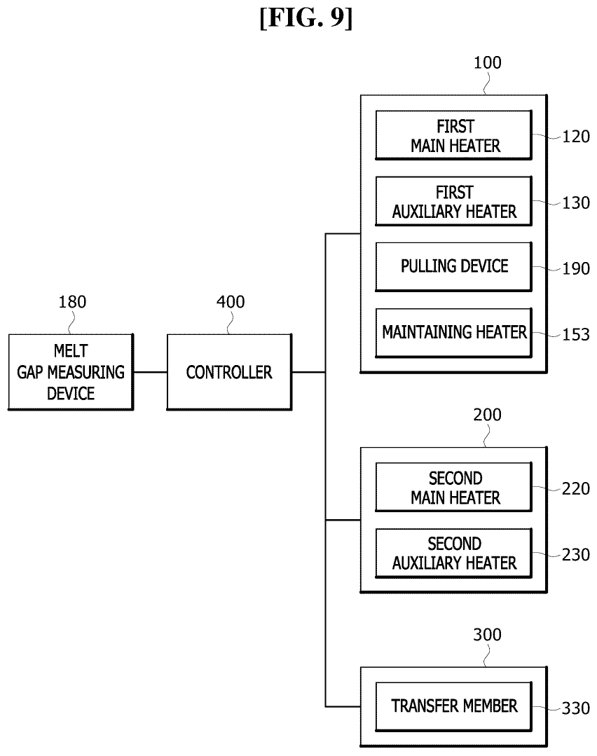

FIG. 1 schematically shows an ingot growth device 10, and FIG. 2 shows a state in which an ingot growth furnace 100 is connected to an auxiliary melting furnace 200. FIG. 3 shows a state in which the auxiliary melting furnace 200 is connected to a silicon feeder 300, and FIG. 4 shows a state in which the ingot growth furnace 100 is connected to the silicon feeder 300. FIG. 5 shows an inner portion of the ingot growth furnace 100, and FIG. 6 shows a first transfer path 150 in detail. FIG. 7 shows an inner portion of the auxiliary melting furnace 200, and FIG. 8 shows an inner portion of the silicon feeder 300. FIG. 9 briefly shows a control block diagram of a controller 400.

Referring to FIGS. 1 to 9, the ingot growth device 10 is a device for growing an ingot IG which is a raw material of a wafer and may be a device, for example, for manufacturing a silicon (Si) gallium arsenide (GaAs) single crystal ingot. The ingot IG manufactured by the ingot growth device 10 may be manufactured into a single crystal silicon wafer for a solar cell. For example, the ingot growth device 10 may be a single crystal silicon ingot growth device using the Czochralski method.

For example, the ingot growth device 10 may include the ingot growth furnace 100 including a main crucible 110, the auxiliary melting furnace 200 which supplies molten silicon MS to the ingot growth furnace 100, the silicon feeder 300 including a solid silicon transfer path 320 connected to the auxiliary melting furnace 200 and a transfer member 330 which is disposed at one side of the solid silicon transfer path 320 and transfers solid silicon S, and the controller 400 which controls at least one of the ingot growth furnace 100, the auxiliary melting furnace 200, and the silicon feeder 300, the ingot growth furnace 100 may further include a melt gap measuring device 180 which measures a melt gap which is a height between an interface of the molten silicon MS accommodated in the main crucible 110 and a reflector 170 located above the main crucible 110, and the controller 400 may increase a supply amount of the solid silicon of the silicon feeder 300 or increase an output of the auxiliary melting furnace 200 when a melt gap is lower than a predetermined range of a normal melt gap and decrease the supply amount of the solid silicon of the silicon feeder 300 or decrease the output of the auxiliary melting furnace 200 when a melt gap is higher than the range of the normal melt gap.

The ingot growth device 10 may include the ingot growth furnace 100, the auxiliary melting furnace 200, the silicon feeder 300, the controller 400, a first connector 500, and a second connector 600.

The ingot growth furnace 100 may receive the molten silicon MS from the auxiliary melting furnace 200 and grow the molten silicon MS into the ingot. The ingot growth furnace 100 may heat the molten silicon at a predetermined temperature and rotate the molten silicon in one direction (for example, clockwise or counter-clockwise in FIG. 5) to grow single crystal silicon. The single crystal silicon may be pulled upward from the ingot growth furnace 100 and grown vertically. In the inner portion of the ingot growth furnace 100, an atmosphere of a vacuum or an inert gas, such as helium or argon, may be maintained.

The ingot growth furnace 100 may include the main crucible 110, a first main heater 120, a first auxiliary heater 130, a pulling wire 140, the first transfer path 150, an opening 160, the reflector 170, the melt gap measuring device 180, and a pulling device 190.

The main crucible 110 may be located in the ingot growth furnace 100 and may heat to melt the silicon. For example, as shown in FIG. 5, the main crucible 110 may have a shape that is concave downward and may accommodate the molten silicon MS therein. The main crucible 110 may receive the molten silicon MS from the auxiliary melting furnace 200 or receive the solid silicon S from the silicon feeder 300 through the first transfer path 150. In addition, the main crucible 110 may be formed of a material with superior heat-resistance such as quartz.

The first main heater 120 may be located around the main crucible 110 or connected to the main crucible 110 and heat the main crucible 110 to maintain a liquid state of the molten silicon MS accommodated in the main crucible 110. For example, as shown in FIG. 5, one or more first main heaters 120 may be located at the lower outside of the main crucible 110. The first main heater 120 may be a resistive heater, and when a current is applied to the main heater 120, the main heater 120 may heat to heat the main crucible 110. In addition, the first main heater 120 may generate an additional magnetic field to circulate the molten silicon MS accommodated in the main crucible 110 to adjust an oxygen concentration.

The first auxiliary heater 130 may surround the main crucible 110 to be spaced apart from the main crucible 110. Like the first main heater 120, the first auxiliary heater 130 may be a resistive heater, and when a current flows in the first auxiliary heater 130, the first auxiliary heater 130 may heat to additionally heat the main crucible 110. The first auxiliary heater 130 may selectively operate according to an amount of the molten silicon MS accommodated in the main crucible 110, a growth rate of the ingot IG, and/or the like.

Power, an output, etc., of each of the first main heater 120 and the first auxiliary heater 130 may be adjusted by the controller 400.

The pulling wire 140 may be inserted through the opening 160 formed in an upper portion of the ingot growth furnace 100, and a seed s may be connected to a lower end of the pulling wire 140. The pulling wire 140 may be rotated and pulled at a predetermined speed by the pulling device 190. The pulling wire 140 may descend to bring the seed s into contact with the molten silicon MS of the main crucible 110 and then ascend while being rotated in one direction (for example, clockwise or counter-clockwise in FIG. 5) by the pulling device 190. Accordingly, the ingot IG may be grown downward from the seed s.

The first transfer path 150 is a path connected to the ingot growth furnace 100 and may receive the molten silicon MS from the auxiliary melting furnace 200 in the state in which the ingot growth furnace 100 is connected to the auxiliary melting furnace 200. The first transfer path 150 is a prismatic or tube type path inserted into a side surface of the ingot growth furnace 100, and an outlet 151 thereof may be located above the main crucible 110. The first transfer path 150 may be inclined downward toward the main crucible 110, and the molten silicon MS supplied from the auxiliary melting furnace 200 may be introduced into the main crucible 110 through the first transfer path 150 and the outlet 151.

Alternatively, in the state in which the ingot growth furnace 100 is connected to the silicon feeder 300, the first transfer path 150 may receive the solid silicon S from the silicon feeder 300. Similarly, the solid silicon may be introduced into the main crucible 110 through the outlet 151 and then melted.

In the first transfer path 150, the outlet 151 may be located in the ingot growth furnace 100, and an inlet 152 may be located outside the ingot growth furnace 100. For example, in the first transfer path 150, the outlet 151 may be located above main crucible 110 so that the molten silicon MS is directly introduced into the main crucible 110. In addition, the inlet 152 may be connected to the auxiliary melting furnace 200 or the silicon feeder 300.

The first transfer path 150 may be located in the first connector 500. For example, as shown in FIGS. 5 and 7, in a state in which at least a portion of the first transfer path 150 is located in the first connector 500, the outlet 151 and the inlet 152 may be externally exposed from the first connector 500.

The first transfer path 150 may include a maintaining heater 153. The maintaining heater 153 may surround at least a portion of the first transfer path 150 and heat the first transfer path 150 to prevent the molten silicon MS supplied from the auxiliary melting furnace 200 from being cooled down and solidified again while the molten silicon MS is moved along the first transfer path 150. Accordingly, a difference in temperature between the molten silicon MS accommodated in the main crucible 110 and molten silicon MS supplied from the first transfer path 150 may be minimized. Alternatively, the maintaining heater 153 may preheat the solid silicon S supplied from the silicon feeder 300 to allow the solid silicon S to be more quickly melted in the ingot growth furnace 100.

For example, the maintaining heater 153 is a resistive heater, and when a current is supplied to the maintaining heater 153, the maintaining heater 153 may heat to heat the first transfer path 150. The maintaining heater 153 may surround an outer circumferential surface of the first transfer path 150 in a longitudinal direction (for example, in an X-axis direction of FIG. 6) of the first transfer path 150. For example, the maintaining heater 153 may be a metal coil surrounding the first transfer path 150.

The maintaining heater 153 may be controlled by the controller 400. For example, the controller 400 may consider an amount of the solid silicon S, an input time of the solid silicon S supplied from the silicon feeder 300, and/or an amount of the molten silicon MS and an input time of the molten silicon MS supplied from the auxiliary melting furnace 200 to control power, an output, etc. of the maintaining heater 153.

The maintaining heater 153 may operate in conjunction with the silicon feeder 300. For example, an output of the maintaining heater 153 may be controlled according to an amount of the solid silicon S supplied to the auxiliary melting furnace 200 from the silicon feeder 300. The controller 400 may adjust the amount of the solid silicon S transferred to the auxiliary melting furnace 200 from the solid silicon transfer path 320 by controlling the transfer member 330 and/or the silicon inputter 340 of the silicon feeder 300. When the transfer member 330 is a vibrator, the controller 400 may calculate a supply amount of the solid silicon of the silicon feeder 300 on the basis of control factors including power (an on/off state) of a power source, a vibration magnitude, and a vibration period of the transfer member 330. In addition, the controller 400 may consider the calculated supply amount of the solid silicon to increase or decrease an output of the maintaining heater 153 such that a melt gap is in the range of the normal melt gap.

The first transfer path 150 may further include a first load cell 154. For example, as shown in FIG. 6, the first load cell 154 may be mounted in the first transfer path 150, measure a weight of the molten silicon MS supplied from the auxiliary melting furnace 200, and transmit the weight to the controller 400. The controller 400 may determine whether a proper amount of the molten silicon MS is supplied to the ingot growth furnace 100 on the basis of the weight measured by the first load cell 154. When the weight measured by the first load cell 154 is outside of a normal range, the controller 400 may increase or decrease a temperature of the second main heater 220 and a temperature of the second auxiliary heater 230 of the auxiliary melting furnace 200 or increase or decrease a supply amount of the solid silicon S of the silicon feeder 300.

The reflector 170 may be located inside the ingot growth furnace 100 and surround the ingot IG. The reflector 170 may be located above the main crucible 110 and prevent heat of the main crucible 110, the first main heater 120, and the first auxiliary heater 130 from being directly applied to the ingot IG.

For example, a lower end of the reflector 170 may be spaced a height H from the molten silicon MS accommodated in the main crucible 110. The height H is a melt gap and may be changed according to an amount of the molten silicon MS accommodated in the main crucible 110.

The melt gap measuring device 180 may be located in the ingot growth furnace 100 to be close to the main crucible 110 and measure a melt gap. For example, the melt gap measuring device 180 is a vision camera and may capture images of the lower end of the reflector 170 and the interface of the molten silicon MS to measure a melt gap and transmit the measured melt gap to the controller 400. Alternatively, the melt gap measuring device 180 may measure a melt gap using a laser or ultrasonic waves.

The pulling device 190 may be disposed above the ingot growth furnace 100, rotate the ingot IG, and pull the ingot IG upward. For example, as shown in FIG. 5, the pulling device 190 may be inserted into the ingot growth furnace 100 through the opening 160 and connected to the pulling wire 140. The seed s may be connected to an end portion of the pulling wire 140, and the pulling device 190 may rotate the pulling wire 140 at a predetermined speed and pull the pulling wire 140 upward to grow the ingot IG from the seed s.

A rotation direction, a rotation speed, and a pulling speed of the pulling device 190 may be controlled by the controller 400. For example, the controller 400 may consider a diameter of the ingot IG to control the rotation direction, the rotation speed, and the pulling speed of the pulling device 190. Alternatively, the controller 400 may consider a melt gap to control the pulling device 190. For example, when a melt gap is lower than the range of the normal melt gap, that is, when an amount of the molten silicon MS accommodated in the main crucible 110 is small, the rotation speed and/or the pulling speed of the pulling device 190 may be decreased. Accordingly, the ingot IG may be grown while maintaining a constant diameter.

The auxiliary melting furnace 200 may supply the molten silicon MS to the ingot growth furnace 100. As shown in FIGS. 1 to 3, the auxiliary melting furnace 200 may be connected to the ingot growth furnace 100 through the first connector 500. Alternatively, the auxiliary melting furnace 200 may be connected to the silicon feeder 300 through the second connector 600. Accordingly, the auxiliary melting furnace 200 may receive the solid silicon from the silicon feeder 300, melt the solid silicon to generate to the molten silicon MS, and supply the molten silicon MS to the ingot growth furnace 100.

The auxiliary melting furnace 200 may include an auxiliary crucible 210, a second main heater 220, a second auxiliary heater 230, a partition wall 240, a second transfer path 250, a first hopper 260, a discharge port 270, a support rod 280, and a guide 290.

The auxiliary crucible 210 may accommodate the solid silicon S input from the silicon feeder 300 and melt the solid silicon S. For example, as shown in FIG. 7, the auxiliary crucible 210 may have a cross section having a deep “U” shape to accommodate the solid silicon S and the molten silicon MS. An upper portion of the auxiliary crucible 210 may be closed by a cover 212, and the auxiliary crucible 210 may be connected to the first hopper 260 through an input port 211. The auxiliary crucible 210 may include a material that is the same as or different from that of the main crucible 110.

The input port 211 is a path through which the solid silicon S supplied from the silicon feeder 300 is introduced into the auxiliary crucible 210 and may be formed above the auxiliary crucible 210. The input port 211 may be formed to be biased to one side of the auxiliary crucible 210. For example, as shown in FIG. 7, the input port 211 may be located at a side opposite to the partition wall 240 and/or the second transfer path 250 based on a central axis of the auxiliary crucible 210. Accordingly, the solid silicon input from the first hopper 260 through the input port 211 may be positioned at a maximal distance from the partition wall 240 and the second transfer path 250. In addition, foreign matter P contained in the unmolten solid silicon or solid silicon may be prevented from being introduced into the second transfer path 250 over the partition wall 240.

The auxiliary crucible 210 may further include the cover 212 and a second load cell 213. For example, as shown in FIG. 7, the cover 212 may cover the upper portion of the auxiliary crucible 210 and include the input port 211 thereinside. For example, the cover 212 may have a disc shape corresponding to the auxiliary crucible 210, and the input port 211 through which the solid silicon S is input may be formed inside the cover 212. The partition wall 240 may extend downward from the cover 212. The second load cell 213 may be attached to a lower portion of the auxiliary crucible 210, measure a weight of the auxiliary crucible 210, and transmit the measured weight to the controller 400. The controller 400 may calculate a weight of the molten silicon MS and a weight of the solid silicon S accommodated in the auxiliary crucible 210 on the basis of the measured weight. The controller 400 may determine whether a proper amount of the solid silicon S is supplied to the auxiliary crucible 210 and whether a proper amount of the molten silicon MS is maintained in the auxiliary crucible 210 on the basis of the weight measured by the second load cell 213. The controller 400 may increase or decrease a temperature of the second main heater 220 and a temperature of the second auxiliary heater 230 of the auxiliary melting furnace 200 or increase or decrease a supply amount of the solid silicon S of the silicon feeder 300 when the weight measured by the second load cell 213 is outside of a normal range.

The second main heater 220 may be close to the auxiliary crucible 210 or attached to the auxiliary crucible 210 and may heat the auxiliary crucible 210 to melt the solid silicon S accommodated in the auxiliary crucible 210. For example, the second main heater 220 may have a shape corresponding to the auxiliary crucible 210, be located under the auxiliary crucible 210, and surround a portion of a lower surface and a side surface of the auxiliary crucible 210.

The second auxiliary heater 230 may be located outside the auxiliary crucible 210 to surround the auxiliary crucible 210. The second auxiliary heater 230 may have a cylindrical shape of which upper and lower portions are open, and the auxiliary crucible 210 may be located in the second auxiliary heater 230. The second main heater 220 and the second auxiliary heater 230 may be electrically heating heaters.

The partition wall 240 may be located in the auxiliary crucible 210 and prevent the solid silicon S and the foreign matter P of the solid silicon S from being introduced into the ingot growth furnace 100 through the second transfer path 250. For example, as shown in FIG. 7, the partition wall 240 may extend downward from an upper surface of the auxiliary crucible 210. The partition wall 240 may be spaced apart from the central axis of the auxiliary crucible 210 toward one side to be close to the second transfer path 250. Accordingly, even when a portion of the solid silicon S and the foreign matter P input to the auxiliary crucible 210 from the first hopper 260 sinks below a surface of the molten silicon MS, the partition wall 240 blocks the second transfer path 250 to prevent the solid silicon S and the foreign matter P from being introduced into the second transfer path 250.

The partition wall 240 may extend across the auxiliary crucible 210. For example, as shown in FIG. 7, the partition wall 240 may not pass through a center of the auxiliary crucible 210, and both ends of the partition wall 240 in a longitudinal direction are disposed between inner surfaces of the auxiliary crucible 210. Accordingly, the partition wall 240 may extend between two facing points of the inner surfaces of the auxiliary crucible 210 and have a shape like a chord. In this case, the partition wall 240 may be fixed to the cover 212 provided on the auxiliary crucible 210 without being fixed to the inner surfaces of the auxiliary crucible 210. Accordingly, there may be gaps between both ends of the partition wall 240 and the inner surfaces of the auxiliary crucible 210, and the solid silicon S and the foreign matter P may accumulate in the gaps.

In the auxiliary crucible 210, since densities of the solid silicon and the foreign matter P are relatively low, the solid silicon and the foreign matter P may mainly float on the surface of the molten silicon MS, and in particular, may be mainly located at an edge along the inner surface of the auxiliary crucible 210. Accordingly, as the solid silicon and the foreign matter P may be intensively located in gaps 2401 between the partition wall 240 and the auxiliary crucible 210, the gaps 2401 may serve to collect other solid silicon and foreign matter P.

A lower end of the partition wall 240 may be located below a lower end of an inlet 251 of the second transfer path 250. Accordingly, the solid silicon S and the foreign matter P close to the partition wall 240 may be more completely prevented from being introduced into the second transfer path 250.

The partition wall 240 may be disposed to be biased toward the second transfer path 250 from the central axis of the auxiliary crucible 210. For example, as shown in FIG. 7, the partition wall 240 may be closer to the inner surface of the auxiliary crucible 210 than to the center of the auxiliary crucible 210.

The second transfer path 250 may be connected to the auxiliary crucible 210 and transfer the molten silicon MS to the first transfer path 150. For example, as shown in FIG. 7, the second transfer path 250 may extend to be inclined downward at one side of the auxiliary crucible 210 close to the partition wall 240. In the state in which the auxiliary melting furnace 200 is connected to the ingot growth furnace 100, the second transfer path 250 may be connected to the first transfer path 150. For example, as shown in FIG. 7, a portion of the second transfer path 250 may be inserted into the inlet 152 of the first transfer path 150. A lower end of the second transfer path 250 may be located above the lower end of the partition wall 240.

The second transfer path 250 may be located at a side opposite to the input port 211 based on the central axis of the auxiliary crucible 210.

The first hopper 260 may be located above the auxiliary crucible 210 and supply the solid silicon supplied from the silicon feeder 300 to the auxiliary crucible 210. For example, as shown in FIG. 6, the first hopper 260 may include the discharge port 270 connected to the silicon feeder 300. In addition, the first hopper 260 may be connected to the auxiliary crucible 210 through the input port 211 and located coaxially with a central axis of the input port 211. The solid silicon S discharged through the discharge port 270 may be input to the auxiliary crucible 210 through the first hopper 260 and the input port 211 and then melted.

The first hopper 260 may have a cylindrical shape, and a lower portion thereof may have an inwardly inclined conical shape. The solid silicon discharged through the discharge port 270 may be input to the input port 211 along an inclined surface of the lower portion.

The support rod 280 may be inserted into the first hopper 260, and an upper end thereof may be connected to an upper end of the auxiliary melting furnace 200 which is not illustrated. In addition, the guide 290 may be located on a lower end of the support rod 280.

The guide 290 may disperse the solid silicon S to prevent the solid silicon S discharged through the discharge port 270 from being biased to and accumulated at any one side in the first hopper 260. For example, as shown in FIG. 7, the guide 290 may have a trapezoidal shape in which a cross-sectional area gradually increases downward and which has an inclined surface at both sides. The solid silicon S discharged through the discharge port 270 may be dispersed toward both sides based on a central axis of the first hopper 260 along the inclined surface of the guide 290 and then fall down.

The silicon feeder 300 may supply the solid silicon S to the ingot growth furnace 100 or the auxiliary melting furnace 200. For example, as shown in FIG. 3, the silicon feeder 300 may be connected to the auxiliary melting furnace 200 and supply the solid silicon S to the auxiliary melting furnace 200, and the auxiliary melting furnace 200 may melt the solid silicon S and supply the molten silicon MS to the ingot growth furnace 100. Alternatively, as shown in FIG. 4, the silicon feeder 300 may be directly connected to the ingot growth furnace 100 and supply the solid silicon S to the ingot growth furnace 100.

The silicon feeder 300 may include a second hopper 310, the solid silicon transfer path 320, and the transfer member 330.

The solid silicon S input to the second hopper 310 moves to the solid silicon transfer path 320 through the connecting port 311. The solid silicon transfer path 320 is a prismatic or tube type path extending in one direction (for example, a Y-axis direction of FIG. 8), and an outlet 321 thereof may face the first hopper 260. In addition, the transfer member 330 may surround the solid silicon transfer path 320 or be located under the solid silicon transfer path 320 and transfer the solid silicon S. For example, the transfer member 330 is the vibrator and may be located on a lower surface of the solid silicon transfer path 320 and vibrate the solid silicon transfer path 320 to move the solid silicon S in the solid silicon transfer path 320. In addition, the controller 400 may control a supply amount of the solid silicon S by controlling at least one of control factors of power (an on/off state) of a power source, a vibration magnitude, and a vibration period of the transfer member 330.

The outlet 321 of the solid silicon transfer path 320 may be located above the guide 290. In addition, the outlet 321 of the solid silicon transfer path 320 may correspond to the discharge port 270. Accordingly, the solid silicon S discharged from the solid silicon transfer path 320 may fall on the guide 290 and then be input to the first hopper 260.

The silicon feeder 300 may further include a silicon inputter 340 and a third load cell 350. The silicon inputter 340 may be located around the second hopper 310 and input the solid silicon S to the second hopper 310. The silicon inputter 340 may receive an instruction from a predetermined program or the controller 400 to input the solid silicon S to the second hopper 310. For example, the controller 400 may adjust an amount of the solid silicon S input from the silicon inputter 340 to control a melt gap. In the drawings, it is illustrated that the silicon inputter 340 is located beside the second hopper 310, but the present invention is not limited thereto. The silicon inputter 340 may be located above the second hopper 310.

The third load cell 350 may be located on the lower surface of the solid silicon transfer path 320 and measure a weight of the solid silicon S positioned in the solid silicon transfer path 320. In addition, the controller 400 may determine whether a proper amount of the solid silicon S is supplied to the solid silicon transfer path 320 on the basis of the weight measured by the third load cell 350. The controller 400 may increase or decrease a supply amount of the solid silicon S of the silicon feeder 300 when the weight measured by the third load cell 350 is outside of a normal range.

In the ingot growth device 10, the components may be modularized, assembled as different combinations, and dissembled. For example, the ingot growth furnace 100, the auxiliary melting furnace 200, and the silicon feeder 300 may be freely assembled with each other and dissembled. For example, the ingot growth furnace 100 and the auxiliary melting furnace 200 may be assembled with each other, the auxiliary melting furnace 200 and the silicon feeder 300 may be assembled with each other, or the ingot growth furnace 100 and the silicon feeder 300 may be assembled with each other. In addition, the ingot growth furnace 100 and the auxiliary melting furnace 200, the auxiliary melting furnace 200 and the silicon feeder 300, or the ingot growth furnace 100 and the silicon feeder 300 may be dissembled from the assembled state. In addition, the ingot growth furnace 100, the auxiliary melting furnace 200, and the silicon feeder 300 may all be assembled with each other.

The components included in the ingot growth device 10 may be modularized such that the components are allowed to be assembled with each other and dissembled. That is, as the ingot growth furnace 100, the auxiliary melting furnace 200, and the silicon feeder 300 are modularized, the ingot growth furnace 100, the auxiliary melting furnace 200, and the silicon feeder 300 may all be assembled as needed, and the solid silicon may be melted using the auxiliary melting furnace 200 and then supplied to the ingot growth furnace 100. Alternatively, the solid silicon may be directly supplied to the ingot growth furnace 100 from the silicon feeder 300 without passing through the auxiliary melting furnace 200. In addition, the ingot growth furnace 100, the auxiliary melting furnace 200, and the silicon feeder 300 may be separated, and maintenance and repair operations may be easily performed thereon.

The controller 400 may be connected to the ingot growth furnace 100, the auxiliary melting furnace 200, and the silicon feeder 300 with and/or without a wire and control the ingot growth furnace 100, the auxiliary melting furnace 200, and the silicon feeder 300. For example, as shown in FIG. 1, the controller 400 may be located on a support frame and be close to the auxiliary melting furnace 200 and/or the silicon feeder 300. For example, the controller 400 may include a processor for various operations, a memory which stores information in advance for controlling the ingot growth furnace 100, the auxiliary melting furnace 200, and the silicon feeder 300, and a communication module for transmitting and receiving signals to and from the ingot growth furnace 100, the auxiliary melting furnace 200, and the silicon feeder 300. In addition, the controller 400 may control a rotation speed and a pulling speed of the pulling device 190 of the ingot growth furnace 100 and a temperature of the first main heater 120, a temperature of the first auxiliary heater 130, and a temperature of the maintaining heater 153. In addition, the controller 400 may control a temperature of the second main heater 220 and a temperature of the second auxiliary heater 230 of the auxiliary melting furnace 200. In addition, the controller 400 may control an input amount of the solid silicon of the silicon feeder 300, power, a magnification, a period, and the like of the transfer member 330.

An integrated circuit structure, which performs control functions using one or more microprocessors or other control devices such as a memory, a processor, a logic circuit, a look-up table, etc., may be used as the controller 400. The controller 400 may be implemented as a portion of a module, a program, or code including one or more executable instructions for executing a specific logic function. The controller 400 may include a processor such as a central processing unit for executing each function or a microprocess or may be implemented using the same. The controller 400 may include a communication device which may transmit and receive data to and from an external device, etc. The communication device may include a combination of one or more of a digital modem, a radio frequency (RF) modem, an antenna circuit, a Wi-Fi chip and associated software, and/or firmware.

When the melt gap is outside of the range of the normal melt gap, the controller 400 may adjust a melt gap to be within the range of the normal melt gap by controlling a supply amount of the solid silicon of the silicon feeder 300 or a supply amount of the molten silicon of the auxiliary melting furnace 200.

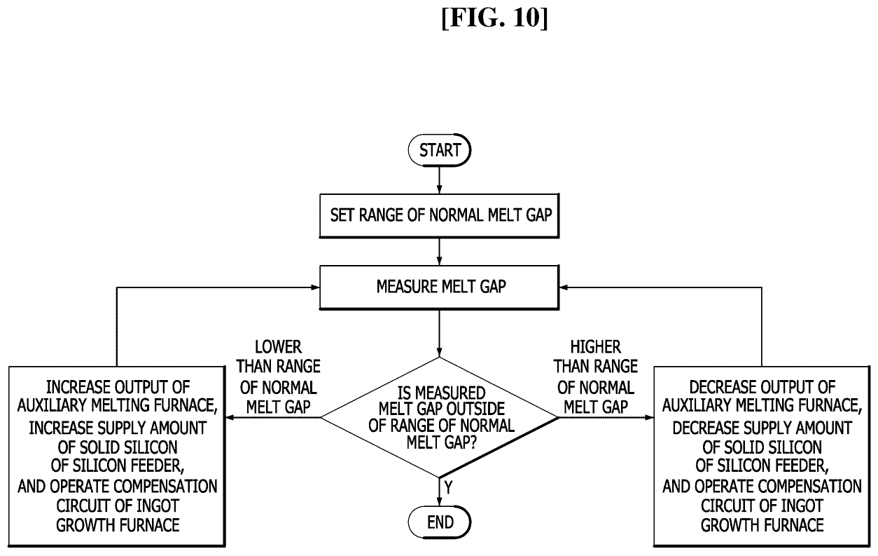

For example, as shown in FIG. 10, the controller 400 may set a range of a normal melt gap. The range of the normal melt gap may be properly selected according to a target diameter and the like of an ingot IG and may be a value input or preset by a user.

Then, the melt gap measuring device 180 may measure a melt gap and transmit the measured melt gap to the controller 400. The controller 400 may compare the corresponding melt gap with the prestored range of the normal melt gap. When the measured melt gap is in the range of the normal melt gap, the controller 400 may finish an operation of controlling a melt gap.

When the measured melt gap is smaller than a lower limit of the range of the normal melt gap, the controller 400 may increase a supply amount of solid silicon of the silicon feeder 300 or a supply amount of molten silicon of the auxiliary melting furnace 200 in order to increase the melt gap. That is, the controller 400 may allow a greater amount of the solid silicon S to be transferred to the auxiliary melting furnace 200 by increasing the supply amount of the solid silicon S input from the silicon inputter 340 or increasing a period or magnitude of the transfer member 330. Alternatively, the controller 400 may increase the amount of the molten silicon MS supplied to the ingot growth furnace 100 from the auxiliary melting furnace 200 by increasing an output of the second main heater 220 and/or an output of the second auxiliary heater 230 of the auxiliary melting furnace 200.

When the measured melt gap is smaller than the lower limit of the range of the normal melt gap, the controller 400 may additionally perform an operation of a compensation circuit of the ingot growth furnace 100. For example, when the measured melt gap is lower than the range of the normal melt gap, a proper range of a diameter of the ingot IG may not be maintained. In order to prevent this, the controller 400 may maintain the proper range of the diameter of the ingot IG by controlling the pulling device 190 to decrease a rotation speed or pulling speed of the pulling wire 140.

Alternatively, when the measured melt gap is greater than an upper limit of the range of the normal melt gap, the controller 400 may decrease a supply amount of the solid silicon of the silicon feeder 300 or a supply amount of the molten silicon of the auxiliary melting furnace 200 in order to decrease the melt gap. That is, the controller 400 may allow a smaller amount of the solid silicon S to be transferred to the auxiliary melting furnace 200 by decreasing the supply amount of the solid silicon S input from the silicon inputter 340 or a period or magnitude of the transfer member 330. Alternatively, the controller 400 may decrease the amount of the molten silicon MS supplied to the ingot growth furnace 100 from the auxiliary melting furnace 200 by decreasing an output of the second main heater 220 and/or an output of the second auxiliary heater 230 of the auxiliary melting furnace 200.

When the measured melt gap is greater than the upper limit of the range of the normal melt gap, the controller 400 may additionally perform an operation of the compensation circuit of the ingot growth furnace 100. For example, when the measured melt gap is greater than the upper limit of the range of the normal melt gap, a proper range of the diameter of the ingot IG may not be maintained. The controller 400 may maintain the proper range of the diameter of the ingot IG by controlling the pulling device 190 to increase a rotation speed or pulling speed of the pulling wire 140.

In addition, the controller 400 may transmit a melt gap measurement signal to the melt gap measuring device 180 again. When the melt gap measured by the melt gap measuring device 180 is in the range of the normal melt gap, the controller 400 may finish the melt gap control, and when the measured melt gap is outside of the range of the normal melt gap, the controller 400 may perform an operation of controlling the melt gap.

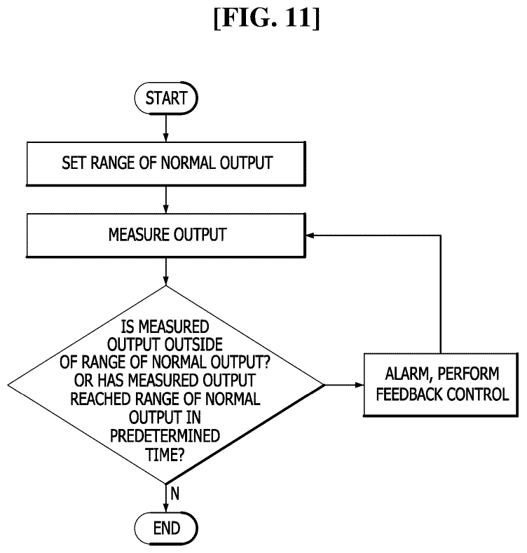

The controller 400 may control an output of the maintaining heater 153. For example, as shown in FIG. 11, the controller 400 may set a range of a normal output of the maintaining heater 153. The range of the normal output may be properly selected according to an amount of molten silicon MS supplied to the auxiliary melting furnace 200 from the silicon feeder 300, an amount of the molten silicon MS supplied to the ingot growth furnace 100 from the auxiliary melting furnace 200, and/or the like, and may be a value input or preset by the user.

Then, a measurement sensor included in the maintaining heater 153 or a separate measurement sensor may measure an actual output of the maintaining heater 153 and transmit the measured actual output to the controller 400. The controller 400 may compare the measured output with the range of the normal output, and when the measured output is in the range of the normal output, the controller 400 may finish an output control operation.

In a case in which the measured output is smaller than a lower limit of the range of the normal output or greater than an upper limit of the range of the normal output, or the measured output has not reached the range of the normal output in a predetermined first time, the controller 400 may visually notify the user of this through a display, or notify the user using a sound, light, etc.

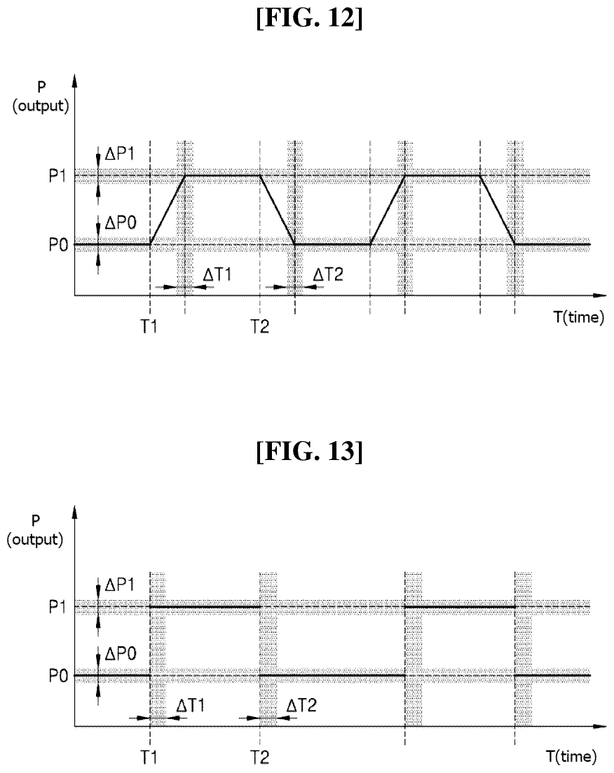

For example, an output of the maintaining heater 153 over time may be as shown in FIG. 12. In a state in which the solid silicon S is not supplied to the auxiliary melting furnace 200 from the silicon feeder 300, that is, the transfer member 330 does not operate, the maintaining heater 153 may maintain an idle output P0. In this case, the controller 400 may more quickly increase the output of the maintaining heater 153 to the range of the normal output and increase a temperature of the first transfer path 150 when solid silicon S is input by maintaining the idle output P0 to be greater than zero.

In a case in which a measured idle output is outside of the range of the normal output, more specifically a range of a normal idle output, the controller 400 may notify the user of this. The range of the normal output may have a predetermined upper limit and a predetermined lower limit based on a target idle output P0, and a difference between the upper limit and the lower limit may be referred to as a difference ΔP0. In a case in which a measured idle output is outside of the range of the normal output, the controller 400 may notify the user of this using the display, light, sound, etc., and the user may control the controller 400 or the maintaining heater 153 such that the idle output is in the range of the normal output. Alternatively, the controller 400 directly performs feedback control on the maintaining heater 153 such that the idle output is in the range of the normal output.

When a time point T1 arrives, the controller 400 may operate the transfer member 330 such that the solid silicon S is moved to the auxiliary melting furnace 200. In addition, at the same time, the controller 400 may control the maintaining heater 153 such that the output increases to a raised temperature output P1. That is, the controller 400 may simultaneously control the transfer member 330 and the maintaining heater 153 at the time point T1. Accordingly, as shown in FIG. 12 the output of the maintaining heater 153 may gradually increase to the raised temperature output P1 from the idle output P0.

In a case in which a measured raised temperature output is outside of a range of a normal output, for example, a range of a normal raised temperature output, the controller 400 may notify the user of this. The range of the normal output may have a predetermined upper limit and a predetermined lower limit based on a target raised temperature output P1, and a difference between the upper limit and the lower limit may be referred to as a difference ΔP1. In a case in which a measured raised temperature output is outside of the range of the normal output, the controller 400 may notify the user of the case using the display, a sound, light, etc., and the user may control the controller 400 or the maintaining heater 153 such that the raised temperature output is in the range of the normal output. Alternatively, the controller 400 may directly perform feedback control on the maintaining heater 153 such that the raised temperature output P1 is in the range of the normal output.

The controller 400 may determine whether a raised temperature output has reached the range of the normal output in a predetermined time. For example, as shown in FIG. 12, when a raised temperature output has reached the range of the normal output within a first time ΔT1 based on a predetermined time point after the time point T1, the controller 400 may determine that the maintaining heater 153 operates normally. However, when a raised temperature output has not reached the range of the normal output within the first time ΔT1 (even when the raised temperature output reaches the range of the normal output after the first time ΔT1 has passed), or a raised temperature output has reached the range of the normal output prior to the first time ΔT1, the controller 400 may determine that the maintaining heater 153 does not operate normally. In this case, the controller 400 may notify the user using the display, a sound, light, etc., and the user may control the controller 400 or the maintaining heater 153.

When a time point T2 arrives after the maintaining heater 153 operates normally in the range of the normal raised temperature output, the controller 400 may finish an operation of the transfer member 330 and adjust the output of the maintaining heater 153 to the idle output P0 again. Accordingly, as shown in FIG. 12, the output of the maintaining heater 153 may gradually decrease to the idle output P0 from the raised temperature output P1.

The controller 400 may determine whether a measured idle output has reached the range of the normal output in a predetermined time. For example, as shown in FIG. 12, when a measured idle output reaches the range of the normal output in the second time ΔT2 based on a predetermined time point after the time point T2, the controller 400 may determine that the maintaining heater 153 operates normally. However, when an idle output does not reach the range of the normal output within the second time ΔT2 (even when the idle output reaches the range of the normal output after the second time ΔT2 has passed), or an idle output has reached the range of the normal output prior to the second time ΔT2, the controller 400 may determine that the maintaining heater 153 does not operate normally. In this case, the controller 400 may notify the user using the display, light, a sound, etc., and the user may control the controller 400 or the maintaining heater 153.

The controller 400 may control an operation of the maintaining heater 153 in conjunction with an operation of the silicon feeder 300. In particular, the controller 400 may optimize an output required to heat the molten silicon MS by controlling the output of the maintaining heater 153 according to the operation of the transfer member 330. In addition, in a case in which an output of the maintaining heater 153 is outside of the range and the time of the normal output, the controller 400 may notify the user of this and perform feedback control to stably supply the molten silicon MS to the ingot growth furnace 100.

As another embodiment, an output of a maintaining heater 153 may be changed intermittently. As shown in FIG. 13, an output of the maintaining heater 153 may be maintained as an idle output P0 and then immediately increased to a raised temperature output P1 when a time point T1 arrives. In addition, when a time point T2 arrives, the output may be decreased to the idle output P0. In this case, a controller 400 may determine whether the maintaining heater 153 operates normally by determining whether the idle output is in a range of a normal idle output within a first time ΔT1 after the time point T1 and whether a raised temperature output is in a range of a normal raised temperature output within a second time ΔT2 after the time point T2. When a measured output is outside of the range of the normal output within the first time ΔT1 or the second time ΔT2 (even when the measured output reaches the range of the normal output after the first time ΔT1 or the second time ΔT2 has passed), the controller 400 may determine that the maintaining heater 153 does not operate normally. In addition, the controller 400 may notify a user using a display, light, a sound, etc., and the user may control the controller 400 or the maintaining heater 153.

The controller 400 may adjust a supply amount of the solid silicon and/or a supply amount of the molten silicon. For example, the controller 400 may receive information of a weight of the molten silicon MS, which moves through the first transfer path 150, from the first load cell 154. In addition, the controller 400 may receive information of a weight of the molten silicon MS and solid silicon S, which are accommodated in the auxiliary crucible 210, from the second load cell 213. When the weight of the molten silicon MS is small in consideration of a state of a melt gap and an ingot IG, the controller 400 may adjust a supply amount of the solid silicon S by controlling the transfer member 330 or the silicon inputter 340 of the silicon feeder 300 or adjust a supply amount of the molten silicon MS by controlling an output of the second main heater 220 and an output of the second auxiliary heater 230 of the auxiliary melting furnace 200.

In addition, the controller 400 may receive information of a weight of the solid silicon S, which moves along the solid silicon transfer path 320, from the third load cell 350. When the weight of the solid silicon S is large or small in consideration of the state of the melt gap and the ingot IG, the controller 400 may increase or decrease an amount of the solid silicon S input from the silicon inputter 340.

The ingot growth furnace 100, the auxiliary melting furnace 200, and the silicon feeder 300 may be connected through the first connector 500 and the second connector 600. For example, the first connector 500 may be connected to the ingot growth furnace 100 and connected to the auxiliary melting furnace 200 or the silicon feeder 300. For example, as shown in FIG. 2, one side of the first connector 500 may be connected to a side surface of the ingot growth furnace 100, and the other side thereof may be connected to a side surface of the auxiliary melting furnace 200. The first connector 500 may be installed such that the first transfer path 150 of the ingot growth furnace 100 and the second transfer path 250 of the auxiliary melting furnace 200 are located inside the first connector 500.

Alternatively, as shown in FIG. 4, one side of the first connector 500 may be connected to the side surface of the ingot growth furnace 100 and connected to a side surface of the silicon feeder 300. The first connector 500 may be installed such that the first transfer path 150 of the ingot growth furnace 100 and the solid silicon transfer path 320 of the silicon feeder 300 are located inside the first transfer path 150. The installation location of the first connector 500 may be set by adjusting a height of a support or frame supporting the auxiliary melting furnace 200 and the silicon feeder 300. The first connector 500 may include a connecting member 510, and the connecting member 510 may be a connecting unit in an airlock type.

One side of the first connector 500 may be fixed to the ingot growth furnace 100. Accordingly, in the state in which the ingot growth furnace 100 is connected to the auxiliary melting furnace 200, the ingot growth furnace 100 may be disconnected from the auxiliary melting furnace 200 and then connected to another auxiliary melting furnace 200 or silicon feeder 300. Alternatively, in the state in which the ingot growth furnace 100 is connected to the silicon feeder 300, the ingot growth furnace 100 may be disconnected from the silicon feeder 300 and then connected to another silicon feeder 300 or auxiliary melting furnace 200.

As shown in FIG. 3, one side of the second connector 600 may be connected to the side surface of the auxiliary melting furnace 200 and the other side thereof may be connected to the side surface of the silicon feeder 300. The second connector 600 may be installed such that the solid silicon transfer path 320 of the silicon feeder 300 is located inside the second connector 600. The installation location of the second connector 600 may be set by adjusting the height of the support or frame supporting the auxiliary melting furnace 200 and the silicon feeder 300. The second connector 600 may include a connecting member 610, and the connecting member 610 may be a connecting unit in an airlock type.

One side of the second connector 600 may be connected to the auxiliary melting furnace 200. Accordingly, in the state in which the auxiliary melting furnace 200 is connected to the silicon feeder 300, the auxiliary melting furnace 200 may be disconnected from the silicon feeder 300 and then connected to another silicon feeder 300. Alternatively, conversely, one side of the second connector 600 may be fixed to the silicon feeder 300. Accordingly, in the state in which the silicon feeder 300 is connected to the auxiliary melting furnace 200, the silicon feeder 300 may be disconnected from the auxiliary melting furnace 200 and then connected to another auxiliary melting furnace 200.

Next, a method of controlling ingot growth will be described. The method of controlling ingot growth may be performed using the ingot growth device 10. The method may include an operation of supplying molten silicon MS to the ingot growth furnace 100 and an operation of growing single crystal silicon while heating the molten silicon MS. In addition, the operation of supplying the molten silicon MS to the ingot growth furnace 100 may include an operation of supplying solid silicon S to the auxiliary melting furnace 200 from the silicon feeder 300, an operation of melting the solid silicon S in the auxiliary melting furnace 200, and an operation of supplying the molten solid silicon S to the ingot growth furnace 100. In addition, the operation of growing single crystal silicon may include an operation of measuring a melt gap of the molten silicon MS accommodated in the main crucible 110 of the ingot growth furnace 100, and in the operation of measuring the melt gap, when a measured melt gap is lower than a range of a normal melt gap, a supply amount of the solid silicon of the silicon feeder 300 may be decreased, or an output of the auxiliary melting furnace 200 may be increased, and when a measured melt gap is higher than the range of the normal melt gap, the supply amount of the solid silicon of the silicon feeder 300 may be decreased, or an output of the auxiliary melting furnace 200 may be decreased.

First, the ingot growth furnace 100 of the ingot growth device 10 is connected to the auxiliary melting furnace 200 and the silicon feeder 300. The ingot growth furnace 100 and the auxiliary melting furnace 200 are connected through the first connector 500, and the auxiliary melting furnace 200 and the silicon feeder 300 are connected through the second connector 600. The inlet 152 is connected to the second transfer path 250 of the auxiliary melting furnace 200 through the first transfer path 150 of the ingot growth furnace 100, and the outlet 151 is disposed above the main crucible 110. In addition, the solid silicon transfer path 320 of the silicon feeder 300 is disposed such that the outlet 321 corresponds to the discharge port 270 of the auxiliary melting furnace 200.

Then, the controller 400 performs an operation of controlling the melt gap. The operation of controlling the melt gap may include the following operations.

First, the controller 400 sets a range of a normal melt gap. The range of the normal melt gap may be properly selected according to specifications of an ingot IG and may be a preset value or a value input by the user.

Then, the melt gap measuring device 180 measures a melt gap. The melt gap measuring device 180 measures the melt gap by measuring a distance between an interface of the molten silicon MS accommodated in the main crucible 110 and the lower end of the reflector 170.

Then, the controller 400 receives information of the measured melt gap from the melt gap measuring device 180 and determines whether the measured melt gap is in the range of the normal melt gap. When the measured melt gap is in the range of the normal melt gap, the controller 400 finishes the operation of controlling the melt gap. When the measured melt gap is smaller than a lower limit of the range of the normal melt gap, the controller 400 increase an output of the second main heater 220 and/or an output of the second auxiliary heater 230 of the auxiliary melting furnace 200 in order to increase the melt gap. Alternatively, the controller 400 increases a transfer amount of the solid silicon S of the silicon inputter 340 of the silicon feeder 300 or increases a magnitude or period of the transfer member 330. Alternatively, the controller 400 may perform an operation of the compensation circuit of the ingot growth furnace 100 to control the pulling device 190 such that a rotation speed or pulling speed of the pulling wire 140 is decreased to maintain a proper range of a diameter of the ingot IG.

When the measured melt gap is greater than an upper limit of the range of the normal melt gap, the controller 400 decreases an output of the second main heater 220 and/or an output of the second auxiliary heater 230 of the auxiliary melting furnace 200 in order to decrease the melt gap. Alternatively, the controller 400 decreases a transfer amount of the solid silicon S of the silicon inputter 340 of the silicon feeder 300 or decreases a magnitude or period of the transfer member 330. Alternatively, the controller 400 may perform an operation of the compensation circuit of the ingot growth furnace 100 to control the pulling device 190 such that a rotation speed or pulling speed of the pulling wire 140 is increased to maintain the proper range of the diameter of the ingot IG.

In addition, the controller 400 transmits a melt gap measurement signal to the melt gap measuring device 180 and determines whether a measured melt gap is in the range of the normal melt gap.

In addition, the controller 400 performs an operation of controlling an output of the maintaining heater 153. The operation of controlling the output may include the following operations.

First, the controller 400 sets a range of a normal output of the maintaining heater 153. The range of the normal output may be properly selected according to the specifications of the ingot IG, and may be a preset value or a value input by the user. In addition, the range of the normal output includes both a range of a normal idle output and a range of a normal raised temperature output.

Then, the controller 400 operates the maintaining heater 153 and the transfer member 330. More specifically, the controller 400 increases a temperature of the maintaining heater 153 at a time point T1 and operates the transfer member 330 at the same time to move the solid silicon S to the auxiliary melting furnace 200 from the solid silicon transfer path 320. In this case, an output of the maintaining heater 153 may be an idle output P1 having a value greater than zero.

Then, the controller 400 determines whether an actual output of the maintaining heater 153 is in the range of the normal output. In this case, the actual output of the maintaining heater 153 may be a value measured by the maintaining heater 153 or a value measured by the separate sensor included in the first transfer path 150. First, the controller 400 determines whether a raised temperature output of the maintaining heater 153 is in the range of the normal raised temperature output. In a case in which a raised temperature output of the maintaining heater 153 is outside of the range of the normal raised temperature output, the controller 400 notifies the user of this or performs feedback control on the maintaining heater 153 such that the raised temperature output is in the range of the normal raised temperature output.

In addition, even in a case in which a raised temperature output of the maintaining heater 153 has not reached the range of the normal raised temperature output within a first time ΔT1 based on a predetermined time after a time point T1 has passed, the controller 400 notifies the user of this or performs feedback control on the maintaining heater 153 such that the raised temperature output is in the range of the normal raised temperature output.

When a set amount of the molten silicon MS is completely transferred to the ingot growth furnace 100 from the auxiliary melting furnace 200, the controller 400 controls the maintaining heater 153 to output an idle output P0, and stops the transfer member 330.

Then, the controller 400 determines whether the idle output of the maintaining heater 153 is in the range of the normal idle output. In a case in which an idle output of the maintaining heater 153 is outside of the range of the normal idle output, the controller 400 notifies the user of this or performs feedback control on the maintaining heater 153 such that the idle output is in the range of the normal idle output

In addition, even in a case in which an idle output of the maintaining heater 153 has not reached the range of the normal idle output within a second time ΔT2 based on a predetermined time after a time point T2 has passed, the controller 400 notifies the user of this or performs feedback control on the maintaining heater 153 such that the idle output is in the range of the normal idle output.

As one example, either of the operation of controlling the melt gap and the operation of controlling the output performed by the controller 400 may be performed first, and the other may be performed later.

While the present invention has been described above with reference to embodiments illustrated in the accompanying drawings, these are only examples. It will be understood by those skilled in the art that various modifications and other equivalent embodiments may be made from the embodiments. Therefore, the technical scope of the present invention will be defined on the basis of the appended claims.

### INDUSTRIAL APPLICABILITY

Embodiments according to the present disclosure can be applied to industries related to ingot growth devices and methods of controlling ingot growth.

1. An ingot growth device comprising:
an ingot growth furnace including a main crucible;
an auxiliary melting furnace which supplies molten silicon to the ingot growth furnace;
a silicon feeder including a solid silicon transfer path connected to the auxiliary melting furnace and a transfer member which is connected to the solid silicon transfer path and transfers solid silicon; and
a controller which controls at least one of the ingot growth furnace, the auxiliary melting furnace, and the silicon feeder,
wherein the ingot growth furnace further includes a melt gap measuring device which measures a melt gap which is a height between an interface of the molten silicon accommodated in the main crucible and a reflector located above the main crucible, and
the controller increases a supply amount of the solid silicon of the silicon feeder or increases an output of the auxiliary melting furnace when the melt gap is lower than a predetermined range of a normal melt gap, and decreases the supply amount of the solid silicon of the silicon feeder or decreases the output of the auxiliary melting furnace when the melt gap is higher than the range of the normal melt gap.

2. The ingot growth device of claim 1, wherein the controller adjusts the supply amount of the solid silicon by controlling at least one of control factors including power, a vibration period, and a vibration magnitude of the transfer member which is a vibrator.

3. The ingot growth device of claim 1, wherein the ingot growth furnace further includes:
a pulling wire in which a seed is connected to an end portion of the pulling wire; and
a pulling device which pulls or rotates the pulling wire upward,
wherein, when the melt gap is outside of the range of the normal melt gap, the controller controls one or more of a rotation speed and a pulling speed of the pulling wire using the pulling device.

4. The ingot growth device of claim 1, wherein:
the ingot growth furnace includes a transfer path which receives the molten silicon from the auxiliary melting furnace and transfers the molten silicon to the main crucible and includes a maintaining heater; and
the controller operates the transfer member and increases an output of the maintaining heater to a raised temperature output at the same time.

5. The ingot growth device of claim 4, wherein the controller outputs an alarm signal when the raised temperature output of the maintaining heater is outside of a range of a normal raised temperature output, or the raised temperature output of the maintaining heater does not reach the range of the normal raised temperature output in a predetermined time from a time point at which the transfer member operates.

6. The ingot growth device of claim 4, wherein the controller operates the maintaining heater while the transfer member does not operate and maintains the output of the maintaining heater as an idle output to be greater than zero and lower than a range of a normal raised temperature output.

7. A method of controlling ingot growth comprising:
supplying molten silicon to an ingot growth furnace; and
growing single crystal silicon while heating the molten silicon,
wherein the supplying of the molten silicon to the ingot growth furnace includes supplying solid silicon from a silicon feeder to an auxiliary melting furnace, melting the solid silicon in the auxiliary melting furnace, and supplying the molten solid silicon to the ingot growth furnace,
the growing of the single crystal silicon includes measuring a melt gap of the molten silicon accommodated in a main crucible of the ingot growth furnace, and
in the measuring of the melt gap, a supply amount of the solid silicon of the silicon feeder is increased, or an output of the auxiliary melting furnace is increased when the measured melt gap is lower than a range of a normal melt gap, and the supply amount of the solid silicon of the silicon feeder is decreased, or the output of the auxiliary melting furnace is decreased when the measured melt gap is higher than the range of the normal melt gap.

8. The method of claim 7, wherein the ingot growth furnace further includes:
a pulling wire in which a seed is connected to an end portion of the pulling wire; and
a pulling device which pulls or rotates the pulling wire upward,
wherein, in the measuring of the melt gap, when the melt gap is outside of the range of the normal melt gap, the pulling device controls one or more of a rotation speed and a pulling speed of the pulling wire.

9. The method of claim 7, wherein:
the ingot growth furnace includes a transfer path which receives the molten silicon from the auxiliary melting furnace and transfers the molten silicon to the main crucible and includes a maintaining heater;
the silicon feeder includes a transfer member which transfers the solid silicon; and
in the supplying of the molten solid silicon to the ingot growth furnace, when a raised temperature output of the maintaining heater is outside of a range of a normal raised temperature output, or the raised temperature output of the maintaining heater does not reach the range of the normal raised temperature output in a predetermined time from a time point at which the transfer member operates, the controller performs feedback control such that the raised temperature output of the maintaining heater is in the range of the normal raised temperature output.

10. The method of claim 9, wherein the controller operates a maintaining heater while the transfer member does not operate and maintains an output of the maintaining heater as an idle output to be greater than zero and lower than a range of a normal raised temperature output.
